(19) United States
(12) Patent Application Publication
(10) Pub. No.: US 2025/0079797 A1
(43) Pub. Date: Mar. 6, 2025

(54) TAPERED-MESA VERTICAL CAVITY SURFACE EMITTING LASER

(71) Applicant: Lumentum Operations LLC, San Jose, CA (US)

(72) Inventors: Albert YUEN, Palo Alto, CA (US); Chien-Yao LU, San Jose, CA (US)

(21) Appl. No.: 18/545,939

(22) Filed: Dec. 19, 2023

Related U.S. Application Data
(60) Provisional application No. 63/535,897, filed on Aug. 31, 2023.

(51) Int. Cl. H01S 5/183; H01S 5/227

(52) U.S. Cl. CPC H01S 5/18352; H01S 5/18305; H01S 5/18377; H01S 5/2275

(57) ABSTRACT

In some implementations, a vertical cavity surface emitting laser (VCSEL) includes a substrate, a first mirror on the substrate, an active region on the first mirror, and a second mirror on the active region. The second mirror may include a plurality of reflector layers. A mesa may be defined in the second mirror. The mesa may taper out from a top surface of the mesa to a periphery of the mesa. A quantity of reflector layers, of the plurality of reflector layers, in sections of the mesa may decrease from a central section of the mesa, underneath the top surface, to the periphery of the mesa.

### CROSS-REFERENCE TO RELATED APPLICATION

This patent application claims priority to U.S. Provisional Patent Application No. 63/535,897, filed on Aug. 31, 2023, and entitled “TAPERED-MESA VERTICAL CAVITY SURFACE EMITTING LASER.” The disclosure of the prior application is considered part of and is incorporated by reference into this patent application.

### TECHNICAL FIELD

The present disclosure relates generally to vertical cavity surface emitting lasers (VCSELs) and to a tapered-mesa VCSEL.

### BACKGROUND

A vertical-emitting laser device, such as a VCSEL, is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

In some implementations, a VCSEL includes a substrate, a first mirror on the substrate, an active region on the first mirror, and a second mirror on the active region. The second mirror may include a plurality of reflector layers. A mesa may be defined in the second mirror. The mesa may taper out from a top surface of the mesa to a periphery of the mesa. A quantity of reflector layers, of the plurality of reflector layers, in sections of the mesa may decrease from a central section of the mesa, underneath the top surface, to the periphery of the mesa.

In some implementations, a VCSEL includes a substrate, a first mirror on the substrate, an active region on the first mirror, and a second mirror on the active region. The second mirror may include a plurality of reflector layers. A mesa may be defined in the second mirror. The mesa may taper out from a top surface of the mesa to a periphery of the mesa. A quantity of reflector layers, of the plurality of reflector layers, in sections of the mesa may decrease from a central section of the mesa, underneath the top surface, to the periphery of the mesa. The VCSEL may include an insulation layer on the second mirror, where the insulation layer has a central opening to expose at least the top surface of the mesa. The VCSEL may include a contact layer on the insulation layer and over the central opening, where the contact layer is electrically connected to the second mirror via the central opening.

In some implementations, a method includes forming a first mirror on a substrate, forming an active region on the first mirror, forming a second mirror on the active region, where the second mirror includes a plurality of reflector layers, and etching the second mirror to define a mesa that tapers out from a top surface of the mesa to a periphery of the mesa. A quantity of reflector layers, of the plurality of reflector layers, in sections of the mesa may decrease from a central section of the mesa, underneath the top surface, to the periphery of the mesa.

### BRIEF DESCRIPTION OF THE DRAWINGS

FIG. 1 shows a sectional view of an example VCSEL.

FIG. 2 shows a close-up sectional view of the example VCSEL of FIG. 1.

FIG. 3 is a flowchart of an example process of forming a tapered-mesa VCSEL.

### DETAILED DESCRIPTION

The following detailed description of example implementations refers to the accompanying drawings. The same reference numbers in different drawings may identify the same or similar elements.

Mode competition in an optical beam, between a fundamental mode and other modes (e.g., non-fundamental or undesired modes), may impact performance of an optical system using the optical beam. For example, mode competition may reduce communication performance, measurement accuracy, three-dimensional (3D) imaging performance, or gesture recognition performance, among other examples. Accordingly, multimode VCSELs can experience noise and increased relative intensity noise (RIN), which leads to poor high-speed performance.

By reducing a number of modes and/or by controlling the modes to be more stable, a high-speed performance of a VCSEL device can be improved. In some examples, top gratings etched into semiconductor, top dielectric films, patterned dielectric and/or metal features, and/or aperture shaping may be used for mode filtering or selection in a multimode VCSEL. However, these techniques may be associated with additional process steps, may need high levels of process control, and/or may use costly equipment for production.

Some implementations described herein provide mode filtering in a multimode VCSEL. In some implementations, the VCSEL may include an active region between a bottom mirror and a top mirror, and a mesa may be defined in the top mirror. The mesa may taper out from a top surface of the mesa toward the active region. In this configuration, a quantity of reflector layers of the top mirror may vary across various sections of the mesa. For example, all of the reflector layers of the top mirror may be in a narrow central section of the mesa beneath the top surface, and a quantity of reflector layers of the top mirror in sections of the mesa may decrease from the central section to a periphery of the mesa.

In this way, lower-order optical modes in the central section may experience optical gain and increase in intensity upon each return path (e.g., due to the central section including the entire structure of the top mirror), whereas optical modes outside of the central section, typically higher-order modes, are in a lossy mirror region (e.g., due to the region outside of the central section including less than the entire structure of the top mirror), and therefore are suppressed (e.g., filtered out) as the optical modes traverse the mesa vertically. Accordingly, the VCSEL described herein may have reduced noise and improved high-speed performance (e.g., improved high-speed stability). Moreover, the taper of the mesa increases a width of the mesa from the top surface to the base of the mesa, thereby reducing an electrical resistance of the VCSEL by allowing electrical current to expand as the current flows vertically down the mesa. Accordingly, the VCSEL described herein may have an improved electrical performance and/or a longer useful life relative to VCSELs that use other mode filtering techniques.

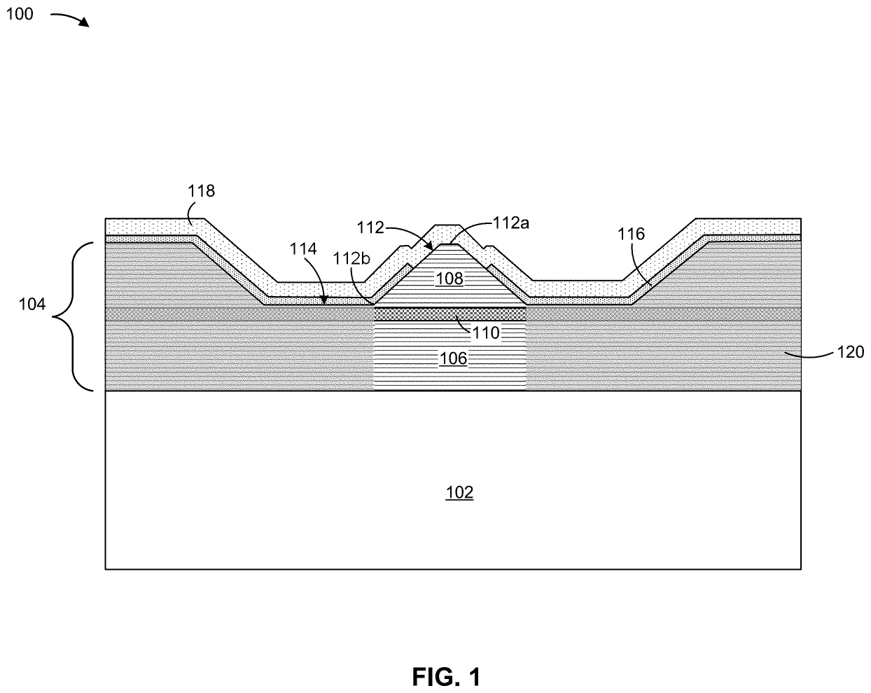

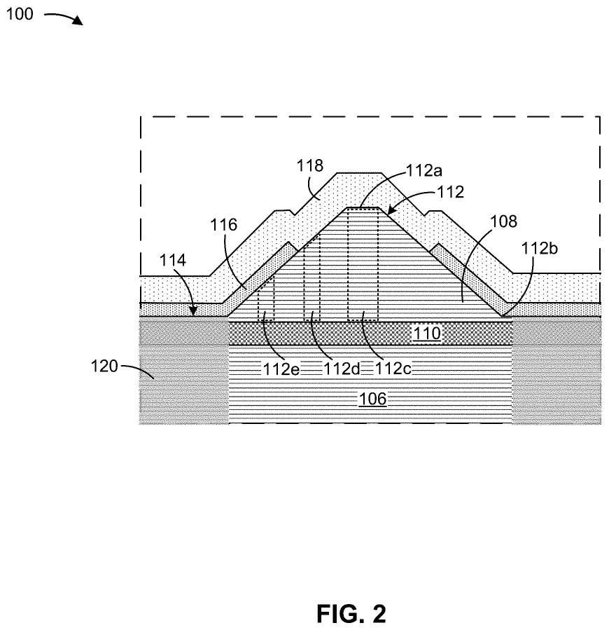

FIG. 1 shows a sectional view of an example VCSEL 100, and FIG. 2 shows a close-up sectional view of the example VCSEL 100. In some implementations, the VCSEL 100 may be included in an array of emitters (e.g., an array of VCSELs 100). In some implementations, as illustrated in FIG. 1, the VCSEL 100 is a bottom-emitting emitter. Alternatively, the VCSEL 100 may, in some implementations, be a top-emitting emitter (e.g., with a similar structure to that shown in FIG. 1, with modifications to enable top-emitting).

The VCSEL 100 may include a substrate 102. The substrate 102 includes a supporting material upon which, or within which, one or more layers or features of the VCSEL 100 are grown or fabricated. In some implementations, the substrate 102 includes an n-type material. In some implementations, the substrate 102 includes a semi-insulating type of material. In some implementations, the substrate 102 may be formed from a semiconductor material, such as gallium arsenide (GaAs), indium phosphide (InP), or another type of semiconductor material.

A set of epitaxial layers 104 may be disposed on (e.g., formed on) the substrate 102. The set of epitaxial layers 104 may include a first mirror 106 (referred to herein as “bottom mirror 106”), a second mirror 108 (referred to herein as “top mirror 108”), and an active region 110 between the bottom mirror 106 and the top mirror 108. For example, the bottom mirror 106 is on the substrate 102, the active region 110 is on the bottom mirror 106, and the top mirror 108 is on the active region 110.

The bottom mirror 106 is a bottom reflector of an optical resonator of the VCSEL 100. For example, the bottom mirror 106 may include a distributed Bragg reflector (DBR), or another type of mirror structure. In some implementations, the bottom mirror 106 is formed from an n-type material. The bottom mirror 106 may include a plurality of reflector layers (e.g., reflector pairs, such as DBR pairs). In some implementations, the plurality of reflector layers (e.g., aluminum gallium arsenide (AlGaAs) layers) may be grown using a metal-organic chemical vapor deposition (MOCVD) technique, a molecular beam epitaxy (MBE) technique, or another technique.

The active region 110 includes one or more layers where electrons and holes recombine to emit light and define the emission wavelength range of the VCSEL 100. The active region 110 may be in the form of a quantum well. The active region 110 may be disposed in an optical cavity defined between the bottom mirror 106 and the top mirror 108.

The top mirror 108 is a top reflector of the optical resonator of the VCSEL 100. For example, the top mirror 108 may include a DBR, or another type of mirror structure. In some implementations, the top mirror 108 is formed from a p-type material. The top mirror 108 may include a plurality of reflector layers (e.g., reflector pairs, such as DBR pairs). In some implementations, the plurality of reflector layers (e.g., AlGaAs layers) may be grown using a MOCVD technique, an MBE technique, or another technique.

A mesa 112 may be defined in the top mirror 108. For example, a moat 114 may be etched down in the top mirror 108 to define a periphery 112b of the mesa 112 (e.g., with the moat 114 surrounding the mesa 112). The mesa 112 may include a top surface 112a (e.g., a surface of the top mirror 108 furthest from the active region 110), and the top surface 112a may be substantially flat. In some implementations, a width (e.g., a diameter) of the top surface 112a may be in a range from 1 micrometer (μm) to 5 μm or in a range from 1 μm to 3 μm. In some implementations, an area of the top surface 112a may be in a shape of a circle, a square, a diamond, or another shape.

The mesa 112 may taper out from the top surface 112a to the periphery 112b of the mesa 112. For example, the mesa 112 may taper toward the active region 110 (e.g., the top mirror 108 may be etched down toward the active region 110). In particular, a base of the mesa 112 may be above the active region 110, such that the active region 110 and the bottom mirror 106 are not part of the mesa 112.

The mesa 112 may taper such that a width (e.g., a diameter) of the top surface 112a is less than a width (e.g., a diameter) across a base of the mesa 112 (e.g., across the periphery 112b of the mesa 112). In other words, the mesa 112 may have a shape of a conical frustum (e.g., the mesa 112 may have a non-zero taper). Thus, due to the taper of mesa 112 (e.g., which increases the width of the mesa 112 from the top surface 112a to the base of the mesa 112), an electrical resistance of the VCSEL 100 is reduced by allowing electrical current to expand as the current flows from the top surface 112a to the base of the mesa 112, thereby improving an electrical performance and/or a useful life of the VCSEL 100.

Due to the taper of the mesa 112, a quantity of reflector layers of the top mirror 108 in various sections of the mesa 112 may vary. A “section” of the mesa 112 may refer to a cross-section of the mesa 112 (e.g., slicing perpendicular to the top surface 112a) or a core section of the mesa 112 (e.g., taken perpendicular to the top surface 112a). In some implementations, all of the reflector layers of the top mirror 108 may be in a central section 112c of the mesa 112 that is underneath the top surface 112a. “Underneath” refers to directly underneath, such that the central section 112c is defined by a boundary that runs perpendicularly from a perimeter of the top surface 112a to the base of the mesa 112. In some implementations, a quantity of reflector layers of the top mirror 108 in sections of the mesa 112 (exemplified in FIG. 2 by sections 112d and 112e) decreases from the central section 112c to the periphery 112b. For example, a first section 112d of the mesa 112, nearer to the central section 112c, may include a greater quantity of reflector layers of the top mirror 108 than a quantity of reflector layers of the top mirror 108 included in a second section 112e of the mesa 112 nearer to the periphery 112b.

In this way, only the central section 112c of the mesa 112 includes the entire structure of the top mirror 108, and less than the entire structure of the top mirror 108 is present outside of the central section 112c. Accordingly, a region of the mesa 112 outside of the central section 112c may exhibit a lossy optical behavior (e.g., may be configured to filter optical modes due to the quantity of reflector layers decreasing). For example, lower-order optical modes in the central section 112c may experience optical gain and increase in intensity upon each return path (e.g., optical modes in the central section 112c are mode selected for lower-order modes), whereas optical modes outside of the central section 112c, typically higher-order modes, are in a lossy mirror region, and therefore are suppressed (e.g., filtered out) as the optical modes traverse the mesa 112 vertically. Thus, the mesa 112 provides mode filtering due to the taper of the mesa 112.

The VCSEL 100 may include an insulation layer 116. The insulation layer 116 may be composed of a dielectric material (e.g., the insulation layer 116 may be a dielectric layer), such as silicon nitride, silicon dioxide, a polymer dielectric (e.g., polyimide), or another type of insulating material. The insulation layer 116 may be disposed on the top mirror 108 (e.g., on the mesa 112). The insulation layer 116 may have a central opening to expose the top surface 112a of the mesa 112 (e.g., to expose at least the top surface 112a of the mesa 112). For example, the central opening in the insulation layer 116 may be wider than the top surface 112a so as to expose the top surface 112a and a region of the mesa 112 surrounding the top surface 112a (but not so wide as to expose the entire mesa 112). In some implementations, the central opening in the insulation layer 116 may be defined by etching the insulation layer 116.

The VCSEL 100 may include a contact layer 118 (e.g., a metal contact layer). In some implementations, the contact layer 118 is formed from a p-type material. In some implementations, the contact layer 118 includes an annealed metallization layer. In some implementations, the contact layer 118 may include a chromium-gold (Cr—Au) layer, a gold-germanium-nickel (AuGeNi) layer, a palladium-germanium-gold (PdGeAu) layer, or the like. The contact layer 118 may be disposed on the insulation layer 116 and over the central opening in the insulation layer 116, and the insulation layer 116 may insulate the contact layer 118 from other layers. The contact layer 118 may be electrically connected (e.g., to allow current to flow) to the set of epitaxial layers 104 via the central opening in the insulation layer 116. For example, the contact layer 118 may be electrically connected to the top mirror 108 via the central opening in the insulation layer 116.

The contact layer 118 may be a first contact layer, and the VCSEL 100 may include a second contact layer (not shown). For example, the VCSEL 100 may include an anode contact and a cathode contact. In some implementations, the second contact layer may be disposed on the substrate 102 (e.g., on a bottom surface of the substrate 102), on an opposite side of the substrate 102 from the set of epitaxial layers 104 (e.g., from the bottom mirror 106). In some implementations, the second contact layer may define an opening (e.g., the second contact may be ring-shaped or partial ring-shaped) through which the VCSEL 100 is to emit light. In some implementations, the second contact layer is formed from an n-type material. In some implementations, the second contact layer includes an annealed metallization layer, in a similar manner as described above. In some implementations, the bottom surface of the substrate 102 may include an anti-reflection coating. For example, the anti-reflection coating may be in the opening defined in the second contact layer.

In some implementations, the VCSEL 100 may include an isolation region 120 (e.g., an isolation implant region) surrounding a region defined underneath the mesa 112 (e.g., in the set of epitaxial layers 104). For example, the isolation region 120 may be an annular region in the set of epitaxial layers 104 underneath the moat 114 so as to surround a cylindrical region in the set of epitaxial layers 104 underneath the mesa 112. The isolation region 120 may be configured to provide current confinement in the VCSEL 100. For example, the isolation region 120 may be a region of the set of epitaxial layers 104 doped with ions of oxygen, hydrogen, or the like (e.g., by ion implantation). Additionally, or alternatively, the VCSEL 100 may include (e.g., within the mesa 112) an oxide aperture (not shown) for current confinement.

By using the tapered mesa 112 in the top mirror 108, the VCSEL 100 may have reduced noise and improved high-speed performance. Moreover, the tapered mesa may reduce an electrical resistance of the VCSEL 100, thereby improving an electrical performance and/or increasing a useful life of the VCSEL 100.

As indicated above, FIGS. 1 and 2 are provided as examples. Other examples may differ from what is described with regard to FIGS. 1 and 2. As an example, the VCSEL 100 may be in a top-emitting configuration. For example, in the top-emitting configuration of the VCSEL 100, the contact layer 118 may define an opening (e.g., the contact layer 118 may be ring-shaped or partial ring-shaped) through which the VCSEL 100 is to emit light. As another example, the contact layer 118 may be a light-transmissive material, such as indium tin oxide (ITO). Moreover, in the top-emitting configuration of the VCSEL 100, the VCSEL 100 may include one or more oxide layers defining oxide apertures (e.g., one or more of which may be in the mesa 112). Furthermore, in the top-emitting configuration of the VCSEL 100, the contact layer 118 may be a first contact layer, and the VCSEL 100 may include a second contact layer (not shown) disposed on the substrate 102 (e.g., on a bottom surface of the substrate 102), on an opposite side of the substrate 102 from the set of epitaxial layers 104. Additionally, a set of layers (e.g., one or more layers) of the VCSEL 100 may perform one or more functions described as being performed by another set of layers of the VCSEL 100, and any layer may comprise more than one layer. Moreover, although the description herein is in terms of a VCSEL, the techniques and structures described herein may be used in connection with another type of vertical emitting (e.g., top emitting or bottom emitting) optical device, such as a light emitting diode (LED), among other examples.

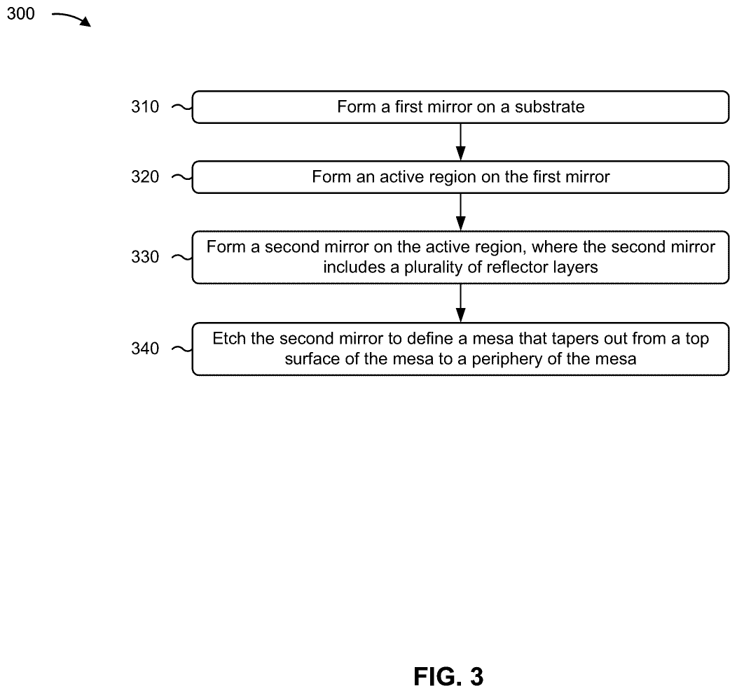

FIG. 3 is a flowchart of an example process 300 of forming a tapered-mesa VCSEL. In some implementations, one or more process blocks of FIG. 3 may be performed by various semiconductor manufacturing equipment.

As shown in FIG. 3, process 300 may include forming a first mirror on a substrate (block 310). For example, the first mirror may be a bottom DBR, as described herein. As further shown in FIG. 3, process 300 may include forming an active region on the first mirror (block 320). As further shown in FIG. 3, process 300 may include forming a second mirror on the active region, where the second mirror includes a plurality of reflector layers (block 330). For example, the second mirror may be a top DBR, as described herein.

As further shown in FIG. 3, process 300 may include etching the second mirror to define a mesa that tapers out from a top surface of the mesa to a periphery of the mesa (block 340). For example, a moat may be etched in the second mirror to define the periphery of the mesa. In some implementations, process 300 may include applying a photoresist dot to the second mirror, and etching the second mirror using the photoresist dot. For example, the etching of the second mirror may be an isotropic etching (e.g., resulting in undercutting of the photoresist dot). The photoresist dot may be greater than 5 μm in diameter, such as from 7 μm to 9 μm in diameter. In some implementations, a quantity of reflector layers, of the plurality of reflector layers, in sections of the mesa decreases from a central section of the mesa, underneath the top surface, to the periphery of the mesa. For example, all of the plurality of reflector layers may be in the central section of the mesa.

In some implementations, process 300 includes performing ion implantation in one or more of the second mirror, the active region, or the first mirror to form an isolation region. For example, the isolation region may surround a region defined underneath the mesa. In some implementations, the ion implantation may be performed using the photoresist dot.

In some implementations, process 300 includes forming an insulation layer on the second mirror, and etching a central opening in the insulation layer to expose the top surface of the mesa. In some implementations, process 300 includes forming a contact layer on the insulation layer and over the central opening. The contact layer may be electrically connected to the second mirror via the central opening.

Although FIG. 3 shows example blocks of process 300, in some implementations, process 300 may include additional blocks, fewer blocks, different blocks, or differently arranged blocks than those depicted in FIG. 3.

In some implementations, an optical source may include the VCSEL 100. In some implementations, an optical system may include the VCSEL 100. Moreover, the optical system may include one or more lenses, one or more optical elements (e.g., diffractive optical elements, refractive optical elements, or the like), one or more reflector elements, and/or one or more optical sensors, among other examples. In some implementations, the VCSEL 100 may be included in (e.g., may be configured for use in) a lidar system or a three-dimensional sensing system.

According to some implementations, a method may include generating an optical pulse for lidar using the VCSEL 100; receiving a signal based on a reflection of the optical pulse from an object; and/or determining a distance and/or a velocity of the object based on the signal. According to some implementations, a method may include generating (or forming) an array of light spots for three-dimensional sensing using the VCSEL 100; receiving signals based on reflection of the light spots from an object; and/or generating a depth map based on the signals. According to some implementations, a method may include generating (or forming) a light pattern for three-dimensional sensing using the VCSEL 100; receiving signals based on reflection of the light pattern from an object; and/or generating a depth map based on the signals.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” “beneath,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL), comprising:
a substrate;
a first mirror on the substrate;
an active region on the first mirror; and
a second mirror, on the active region, comprising a plurality of reflector layers,
wherein a mesa is defined in the second mirror,
wherein the mesa tapers out from a top surface of the mesa to a periphery of the mesa, and
wherein a quantity of reflector layers, of the plurality of reflector layers, in sections of the mesa decreases from a central section of the mesa, underneath the top surface, to the periphery of the mesa.

2. The VCSEL of claim 1, wherein all of the plurality of reflector layers are in the central section of the mesa.

3. The VCSEL of claim 1, further comprising:
an insulation layer on the second mirror,
wherein the insulation layer has a central opening to expose at least the top surface of the mesa.

4. The VCSEL of claim 3, further comprising:
a contact layer on the insulation layer and over the central opening,
wherein the contact layer is electrically connected to the second mirror via the central opening.

5. The VCSEL of claim 4, wherein the contact layer is a first contact layer, and
wherein the VCSEL further comprises:
a second contact layer on the substrate on an opposite side of the substrate from the first mirror.

6. The VCSEL of claim 1, further comprising:
an isolation region surrounding a region defined underneath the mesa.

7. The VCSEL of claim 1, wherein the mesa tapers toward the active region.

8. The VCSEL of claim 1, wherein a region of the mesa outside of the central section of the mesa is configured to filter out optical modes.

9. The VCSEL of claim 1, wherein the mesa has a shape of a conical frustum.

10. A vertical cavity surface emitting laser (VCSEL), comprising:
a substrate;
a first mirror on the substrate;
an active region on the first mirror;
a second mirror, on the active region, comprising a plurality of reflector layers,
wherein a mesa is defined in the second mirror,
wherein the mesa tapers out from a top surface of the mesa to a periphery of the mesa, and
wherein a quantity of reflector layers, of the plurality of reflector layers, in sections of the mesa decreases from a central section of the mesa, underneath the top surface, to the periphery of the mesa;
an insulation layer on the second mirror,
wherein the insulation layer has a central opening to expose the top surface of the mesa; and
a contact layer on the insulation layer and over the central opening,
wherein the contact layer is electrically connected to the second mirror via the central opening.

11. The VCSEL of claim 10, wherein all of the plurality of reflector layers are in the central section of the mesa.

12. The VCSEL of claim 10, wherein the VCSEL is a bottom-emitting emitter.

13. The VCSEL of claim 10, wherein the periphery of the mesa is defined in the second mirror by a moat etched down in the second mirror.

14. The VCSEL of claim 10, wherein the mesa tapers toward the active region.

15. A method, comprising:
forming a first mirror on a substrate;
forming an active region on the first mirror;
forming a second mirror on the active region,
wherein the second mirror comprises a plurality of reflector layers; and
etching the second mirror to define a mesa that tapers out from a top surface of the mesa to a periphery of the mesa,
wherein a quantity of reflector layers, of the plurality of reflector layers, in sections of the mesa decreases from a central section of the mesa, underneath the top surface, to the periphery of the mesa.

16. The method of claim 15, further comprising:
applying a photoresist dot to the second mirror,
wherein etching the second mirror uses the photoresist dot.

17. The method of claim 16, further comprising:
performing, using the photoresist dot, ion implantation in one or more of the second mirror, the active region, or the first mirror to form an isolation region,
wherein the isolation region surrounds a region defined underneath the mesa.

18. The method of claim 15, further comprising:
forming an insulation layer on the second mirror; and
etching a central opening in the insulation layer to expose the top surface of the mesa.

19. The method of claim 18, further comprising:
forming a contact layer on the insulation layer,
wherein the contact layer is electrically connected to the second mirror via the central opening.

20. The method of claim 15, wherein all of the plurality of reflector layers are in the central section of the mesa.
